(19) United States
(12) Patent Application Publication
(10) Pub. No.: US 2025/0338412 A1
(43) Pub. Date: Oct. 30, 2025

(54) HALF-WIDTH RACK DEVICE LATCHING MECHANISM

(71) Applicant: HEWLETT PACKARD ENTERPRISE DEVELOPMENT LP, Spring, TX (US)

(72) Inventors: Tatt Hoong Chow, Singapore (SG); Foo Luen Wong, Singapore (SG)

(21) Appl. No.: 18/648,832

(22) Filed: Apr. 29, 2024

(51) Int. Cl. H05K 5/02; H05K 7/14

(52) U.S. Cl. CPC H05K 5/0221; H05K 7/1489

(57) ABSTRACT

A half-width rack-mountable information processing device comprises a chassis, information processing components, and a latching mechanism to secure the chassis in a half-width compartment of a mounting tray, which is attachable to a rack. The latching mechanism comprises a fixed portion comprising a first grasping surface, and a movable portion pivotably coupled to the fixed portion and comprising a latch and a second grasping surface. The second grasping surface is movable between a first extreme and a second extreme. In the first extreme, the first and second grasping surfaces are farthest apart and the latch is in a latching position. In the second extreme, the first and second grasping surfaces are closet together and the latch is in an unlatched position, The first and second grasping surfaces have, while in the second extreme, a positive non-zero angle therebetween.

### INTRODUCTION

Some information processing devices (computers, networking devices, etc.) are mountable to a rack (also called a server rack). Such devices may also be referred to herein as rack-mountable devices. A rack is a supporting structure which has vertical posts (usually four) which have mounting features (e.g., apertures) arranged at predetermined positions along the height of the posts to define multiple vertically stacked installation positions for rack-mountable devices. A rack-mountable device may be mounted to the rack by positioning the device in one of the installation positions and engaging fasteners of the device with the mounting features of the rack. In some cases, sliding or telescoping rails may be attached to the rack and the rack-mountable device may be attached to the rails to allow the device to be pulled horizontally out of the rack, e.g., for maintenance/service, without having to fully detach the device from the rack.

There are various industry standards specifying form factors for racks, including specifications for the width of the rack and for the positions for the mounting features. Specifically, in many rack standards, the mounting features are arranged to define installation positions spaced apart by a rack unit (abbreviated as U). A rack unit (U) is a unit of measure equal to 1¾ inches (44.45 mm). Many rack-mountable devices have heights which are approximately equal to one U or a multiple thereof (in practice, slightly less, to avoid interference during insertion/removal), and are often described in terms of this height, such as “1U” device (referring to a rack-mountable device which has a height of 1U), “2U” device to (referring to a rack-mountable device which has a height of 2U), and so on. In addition, many rack-mountable devices have widths which are based on a particular form of rack. For example, standard or “full-width” rack-mountable devices have a width which is approximately equal to (or slightly larger than) the width of a front opening of a corresponding rack form factor so that the device spans the opening when installed. As another example, a “half-width” device, has a width which is approximately half the width of the front opening so that two such half-width devices can be positioned side-by-side within the same vertical mounting position. (Often, the width of the device is only specified if it is less than the full-width, so that “1U” may refer to a device which is 1U tall and full-width, whereas “1U half-width” may refer to a device which is 1U tall and half-width.)

### BRIEF DESCRIPTION OF THE DRAWINGS

The present disclosure can be understood from the following detailed description, either alone or together with the accompanying drawings. The drawings are included to provide a further understanding of the present disclosure and are incorporated in and constitute a part of this specification. The drawings illustrate one or more examples of the present teachings and together with the description explain certain principles and operations. In the drawings:

FIG. 1 is a block diagram schematically illustrating an example half-width rack-mountable information processing device and an example latching mechanism thereof.

FIG. 2 is a block diagram schematically illustrating an example system comprising the information processing device of FIG. 1, a mounting tray, a rail, and a rack to which the information processing device is mountable via the mounting tray and rail.

FIG. 3 is a perspective view of another example system comprising another example rack-mountable half-width information processing device, a mounting tray, a rail, and a rack to which the information processing device is mountable via the mounting tray and rail.

FIG. 4 is an exploded perspective view of the latching mechanism of the information processing device of FIG. 3.

FIG. 5 is a side view of a first side the latching mechanism of FIG. 4 with a movable potion thereof made semi-transparent to reveal underlying structures. Structures which are covered by the semi-transparent movable portion are referenced in FIG. 5 with dashed lead lines.

FIG. 6 is cross-section of the latching mechanism of FIG. 4 taken along the plane 6-6 indicated in FIG. 5.

FIG. 7 a side view of a second side of the latching mechanism of FIG. 4.

FIG. 8 a side view of the information processing device of FIG. 3 with the latching mechanism thereof in an unactuated and latched state.

FIG. 9 is a side view of the information processing device of FIG. 3 with the latching mechanism thereof in an actuated and unlatched second state.

FIGS. 10-13 illustrate a sequence of events associated with installing the information processing device of FIG. 3 in the mounting tray. FIG. 10 is a side view showing the information processing device in a first state in which the information processing device has been advanced rearward part way into the mounting tray. FIG. 11 is a side view showing the information processing device in a second state, reached by advancing the information processing device farther rearward into the mounting tray, in which a latch of the latching assembly is contacting a latch receiver pin of the mounting tray. FIG. 12 is a side view showing the information processing device in a third state, reached by advancing the information processing device farther rearward into the mounting tray, in which the latch is displaced vertically by the latch receiver pin. FIG. 13 is a side view showing the information processing device in a fourth state (installed state), reached by advancing the information processing device farther into the mounting tray, in which a hook of the latch is engaged with the latch receiver pin, corresponding to a latched state of the latching mechanism.

FIGS. 14-16 illustrate a sequence of events associated with removing the information processing device of FIG. 3 from the mounting tray. FIG. 14 is a side view showing the information processing device in the installed state. FIG. 15 is a side view showing the information processing device in the fifth state, reached by a user squeezing grasping surfaces of the latching assembly together and thereby moving a movable portion of the latching assembly, in which the latch is vertically moved and the hook thereof is disengaged from the latch receiver pin. FIG. 16 is a side view showing the information processing device in the sixth state, reached by moving the information processing device forward while continuing to squeeze the grasping surfaces, in which the latch is moved forward past the latch receiver pin.

FIG. 17 is a front detail view of a portion of the system of FIG. 3 showing two of the information processing devices in an installed state in the mounting tray.

### DETAILED DESCRIPTION

Because a half-width rack-mountable device does not span the full width of the rack and thus cannot directly attach to both front posts or both back posts, additional equipment may be needed to allow for their secure mounting to the rack. One approach is to use a mounting tray, which spans the full width of the rack and is mounted thereto. The mounting tray may be a shaped like a box with two horizontally adjacent compartments therein which are each dimensioned to receive a half-width rack-mountable device.

However, because the half-width rack-mountable device is not secured directly to the rack, it may need to be secured (attached) to the mounting tray, to prevent the device from inadvertently coming out of the rack (e.g., due to shock, vibration, etc.). Securing the half-width rack-mountable device to the mounting tray can be challenging because the assembly is very space constrained. Many information processing devices are space constrained already, but this can be even further exacerbated in half-width devices because the mounting tray takes up some space which might otherwise be usable for the device, so that the half-width device is actually slightly less than half the size of a full-width device. Accordingly, space may be at a premium in the half-width device, which may preclude the use of certain bulky attachment mechanisms used in other contexts.

In addition, in some circumstances, it may be desired to allow for easy removal of the half-width device from the mounting tray, for example for maintenance/service. In particular, it may be desired in some contexts for the user to be able to remove the device using only one hand, so that the user's other hand can hold onto something else. However, in many systems, a user may need to apply a non-trivial amount of force to pull the device out of the mounting tray, e.g., due to friction. Moreover, due to the small size of the half-width devices, structures such as large pull handles which might make the pulling easier are usually not present. Consequently, a user may have some difficulty pulling the device out of the tray, and often may need to use both hands together in order to do so.

To address these and other issues, examples disclosed herein provide half-width rack-mountable information processing devices with a latching mechanism to secure the device to a mounting tray, where the latching mechanism is designed to be space optimized and to facilitate easy removal (in some cases, one-handed removal) of the device from the mounting tray. The latching mechanism may comprise a fixed portion which is mounted to a lateral side of the information processing device and a movable portion which is pivotably coupled to the fixed portion. The movable portion may comprise a latch at one end which protrudes rearward (toward the mounting tray) and an arm at the other end which protrudes forward (away from the mounting tray). A latch receiver (e.g., pin) is positioned inside the mounting tray horizontally protruding from a vertical support structure (e.g., central divider wall or side wall) so the latch engages the latch receiver when the information processing devices is inserted into the mounting tray. The fixed portion also has an arm which protrudes forward out of the mounting tray. The arms of the fixed and movable portions each have a handle, with the two handles being arranged opposite one another along a vertical direction. By squeezing the handles towards one another, the movable portion pivots and the latch thereof moves vertically, thus unlatching the latch from the latch receiver.

The parts of the fixed and movable portions which protrude rearward into the mounting tray are relatively thin in a widthwise (lateral) dimension (about 4.0 mm, in some examples), which allows the latching mechanism to fit between the sidewall of the device and the vertical support of the mounting tray while only taking a small amount of space away from the device. Thus, a secure latching mechanism can be provided for the half-width rack mountable device notwithstanding the highly space constrained context.

In addition, the handles of the latching portion may be configured to facilitate easier removal of the rack mountable device. In some examples, the handles provide grasping surfaces arranged such that, when the handles are squeezed toward one another to the greatest extent of their travel, there is a positive non-zero angle between their grasping surfaces—for example, the bottom handle's grasping surface may be tilted downward from horizontal and the top handle's grasping surface may be tilted upward from horizontal. The wide grasping surfaces and their positive angling relative to one another allow the user to obtain a secure grip on the grasping surfaces even when squeezing with only moderate strength, which can enable a user to pull the device out of the mounting tray using the latching mechanism handles. In other words, the angled grasping surfaces give the user something to pull against in the forward direction, effectively increasing the friction between their fingers and the handles for a given amount of squeezing force (as compared to other arrangements, such as handles with parallel surfaces or negatively angled surfaces), thus allowing the user to apply less squeezing force and yet still maintain traction on the handles. Moreover, because the pulling out of the device can be accomplished using the same set of handles which are used to unlatch the latching mechanism, in some examples a user can remove the device using just one hand. For example, the user grasps the handles with one hand, squeezes them together to unlatch the latching mechanism, and while still squeezing the handles together, pulls forward on the handles to remove the device.

Furthermore, in some examples the latching mechanism may be manufacturable using relatively inexpensive and simple manufacturing techniques. For example, the fixed and movable portions of the latching mechanism may be formed from sheet metal which is stamped into the desired shape, which is a relatively simple and inexpensive process. This is in contrast to other types of fasteners which may be formed from machined parts which can be more expensive than stamped sheet metal.

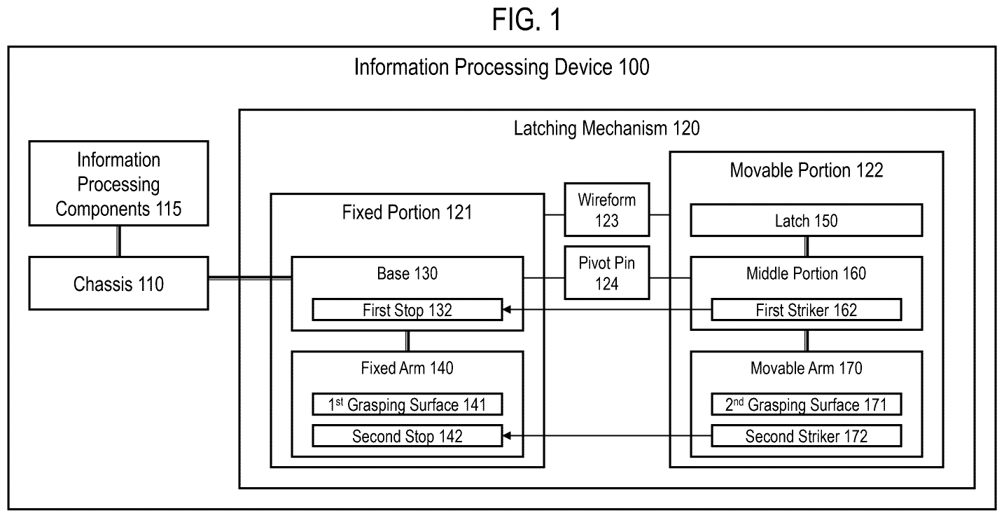

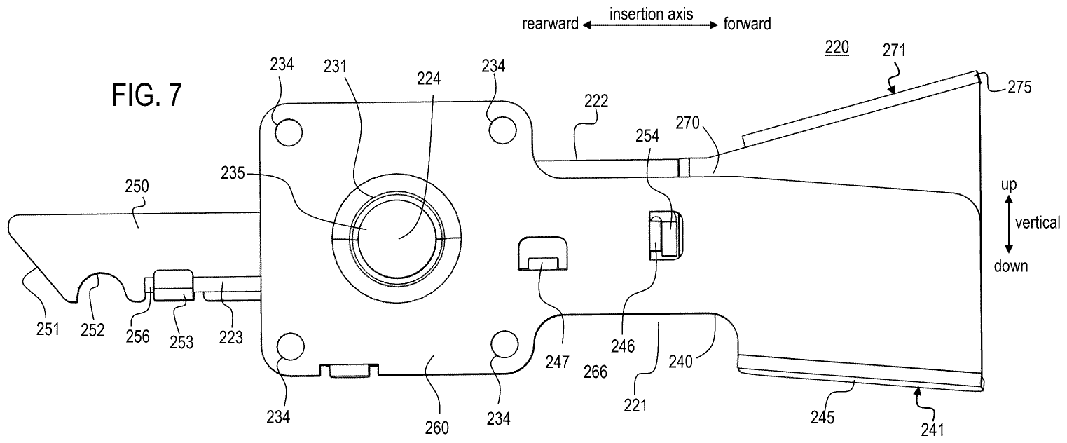

These and other aspects of examples disclosed herein will be described in greater detail below in relation to FIGS. 1-17.

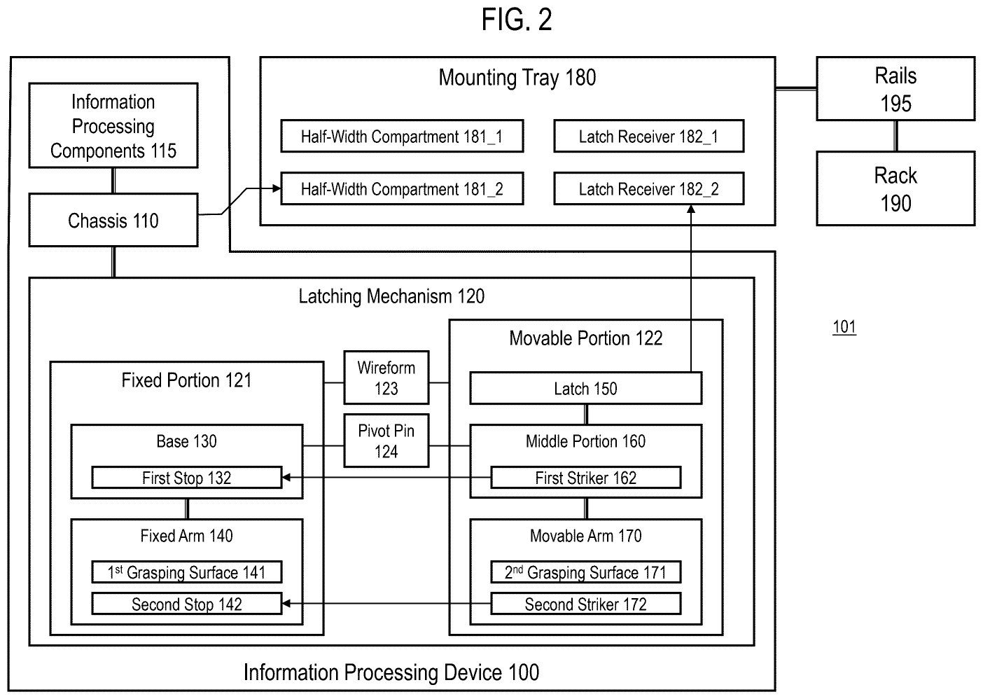

FIG. 1 illustrates an example half-width rack-mountable information processing device 100 (information processing device 100 or device 100) comprising a latching mechanism 120. FIG. 2 illustrates a system 101 comprising the information processing device 100 together with a rack 190 to which the device 100 is mountable (via mounting tray 180). FIGS. 1 and 2 are schematic in nature and are not intended to illustrate shapes, sizes, or other structural details accurately or to scale. Some examples of the device 100 or system 101 may include components which are not illustrated in FIG. 1 or 2, and one or more components illustrated in FIG. 1 or 2 may be omitted from the device 100 or system 101 in some examples. In FIGS. 1 and 2, fixed physical connections (attachments) between components are indicated conceptually by double solid lines; physical engagements (but not necessarily fixed attachments) between components are indicated conceptually by solid lines; and physical engagements which are intermittent (e.g., they depend on the states or positions of the components) are indicated by sold lines with arrows.

The device 100 and system 101 will be described together below, with reference to FIGS. 1 and 2, for ease of understanding.

The information processing device 100 may be, for example, a computer (e.g., server), networking device (e.g., network switch, router, etc.), or other information processing equipment. As shown in FIG. 1, the information processing device 100 comprises a chassis 110, information processing components 115, and a latching mechanism 120. These will be described in turn below.

The chassis 110 comprises supporting structures which support and, in some cases, house (enclose) the information processing components 115. For example, the chassis 110 may have a box-like structure with a basepan (bottom wall), lateral sidewalls, a cover (top wall), and front and back panels. The front and back panels are not necessarily completely solid and may comprise openings such as bays to receive removable modules, connectors (e.g., sockets) to receive connectors of cables of other devices, and perforations for airflow. In some instances, the cover may be removable to allow access to components inside the chassis.

The information processing components 115 may include any electronic, optical, or opto-electronic, devices which are configured to process information. Processing information, in this context, can include manipulating the information, storing the information, retrieving the information from storage, or routing the information to a destination. Thus, for example, the information processing components 115 may include a primary system board (e.g., motherboard) which comprises a processor, application-specific-integrated-circuitry (ASIC), complex-programmable-logic-device (CPLD), or other logic device. As another example, the information processing components 115 may include memory devices (e.g., random access-memory (RAM)) or storage devices (e.g., solid state drives (SSDs)). As another example, the information processing components 115 may include electrical or optical connectors, such as the ports of a network switch or router.

The latching mechanism 120 comprises a fixed portion 121, a movable portion 122 pivotably coupled to the fixed portion, a wireform 123, and a pivot pin 124. These components will be described in turn below.

The fixed portion 121 comprises a base 130 which is fixedly attached to the chassis 110. For example, the base 130 may be attached to a side wall of the chassis 110 near a front end thereof. The base 130 may be attached to the chassis 110 by mechanical fasteners, such as screws, rivets, or other fasteners. Alternatively, the base 130 may be attached to the chassis 110 by welding, brazing, adhesives, or any other attachment technique. Thus, the fixed portion 121 is stationary relative to the chassis 110. Attached to the base 130 is a fixed arm 140. The fixed arm 140 protrudes from the base 130 in a forward direction (a direction which is away from the mounting tray 180 when the device 100 is installed therein). The fixed arm 140 comprises a handle which has a first grasping surface 141, with the handle protruding from the mounting tray 180 in the installed state of the device 100 therein. The fixed portion 121 also comprises a first stop 132 (in the base 130) and a second stop 142 (in fixed arm 140). Grasping surface 141, first stop 132, and second stop 142 will be described in more detail below in conjunction with the parts of the movable portion 122 with which they interact.

Movable portion 122 comprises a middle portion 160, which is pivotably coupled to the base 130 of the fixed portion 121 by pivot pin 124. More specifically, in some examples, a pivot axis about which the movable portion 122 pivots is parallel to a width dimension of the information processing device (i.e., a direction parallel to both side walls of the chassis 110). The fixed portion 121 and/or movable portion 122 may include engagement features (not illustrated) with which the pivot pin 124 engages to provide the pivotable attachment. The engagement features may include, for example, an aperture (hole) through which the pivot pin 124 extends. In some examples, the pivot pin 124 is fixedly attached and immobile relative to the fixed portion 121 and movable relative to the movable portion 122 (e.g., the movable portion can rotate relative to the pin 124 and thereby pivot relative to the fixed portion 121). In other examples, the pivot pin 124 is fixedly attached and immobile relative to the movable portion 122 and movable relative to the fixed portion 121 (e.g., the pin 124 can rotate relative to the fixed portion 121 and thus the movable portion 122, attached to the pin 124, pivots relative to the fixed portion 121). In still other examples, the pin 124 is movable relative to both the movable portion 122 and the fixed portion 121 (e.g., the pin 124 can rotate relative to either or both).

The movable portion 122 also comprises a latch 150 protruding in a rearward direction (a direction pointing into the mounting tray 180 in the installed state of the device 100) from the middle portion 160. The latch 150 comprises a latching engagement element, such as a hook, protrusion, recess, etc., which is configured to engage a latch receiver 182 of the mounting tray in a manner that latches the device 100 to the mounting tray 180 (i.e., prevents or resists removal of the device 100). For example, in one implementation, the latch 150 comprises a hook and the latch receiver 182 comprises a pin which is received in the hook. Because the pivot axis about which the movable portion 122 pivots is parallel to the width dimensions, the end of the latch 150 moves vertically up and down along an arc when the movable portion 122 pivots. In some examples, the latch 150 is configured such that a bottom side thereof engages with a top side of the latch receiver 182, such that the latch 150 can be disengaged from the latch receiver 182 by pivoting the movable portion 122 in a direction that moves the latch 150 upward and off the latch receiver 182. In other examples, the latch 150 is configured such that a top side thereof engages with a bottom side of the latch receiver 182, such that the latch 150 can be disengaged from the latch receiver 182 by pivoting the movable portion 122 in a direction that moves the latch 150 downward and off the latch receiver 182.

The movable portion 122 also comprises a movable arm 170. The movable arm 170 protrudes in the forward direction from the middle portion 160, i.e., the opposite direction from the latch 150. Thus, the movable arm 170 extends generally parallel to and alongside the fixed arm 140 of the fixed portion 121. Like the fixed arm 140, the movable arm 170 has a handle at an end thereof, with the handle having a second grasping surface 171. Moreover, because the pivot axis is located between the movable arm 170 and the latch 150, if an upward or downward force is applied to the handle of the movable arm 170, this generates a torque which tends to pivot the movable portion 122 and moves the latch 150 in a direction opposite that of the applied force. In other words, the movable portion 122 acts like a first class (or class one) lever. Accordingly, in examples in which the latch 150 is moved upward to disengage it from the latch receiver 182, the second grasping surface 171 may be arranged to face generally upward so that a user can apply a downward force to the second grasping surface 171 to drive disengagement of the latch 150. On the other hand, in examples in which the latch 150 is moved downward to disengage it from the latch receiver 182, the second grasping surface 171 may be arranged to face generally downward so that a user can apply an upward force to the second grasping surface 171 to drive disengagement of the latch 150.

The first and second grasping surfaces 141 and 171 may be vertically spaced apart from each other, are aligned or overlapping in a vertical direction, and face in generally opposite directions. This allows the user to apply a force to the second grasping surface 171 by grasping both the first and second grasping surfaces 141 and 171 between thumb and opposing finger and squeezing the two towards one another (e.g., in a pinching motion). Accordingly, in some examples in which latch 150 is moved upwards to disengage, the handle of the movable arm 170 is positioned vertical above the handle of the fixed arm 140, with second grasping surface 171 facing generally upwards and first grasping surface 141 facing generally downwards. In other examples in which latch 150 is moved downwards to disengage, the handle of the fixed arm 140 is positioned vertical above the handle of the movable arm 170, with second grasping surface 171 facing generally downwards and first grasping surface 141 facing generally upwards. Note that when reference is made herein to the grasping surfaces facing in opposite directions, this does not mean that the two surfaces face directions which are exactly 180 degrees opposite one another. Rather, because the grasping surfaces 141 and 171 may be angled relative to one another, they may face in directions which are generally opposite one another in the sense of one facing generally downward and the other facing generally upward. More rigorously, a surfaces faces in a direction pointed to by a normal vector thereto, which is a vector that begins at a point on the surface and extends perpendicularly away from the surface, and the grasping surfaces 141 and 171 are regarded herein as facing in opposite directions if the normal vector of one surface has a negative value in the component thereof representing the vertical dimension (i.e., the vector points at least partially downward) while the normal vector of the other surface has a positive value in the component thereof representing the vertical dimension (i.e., the vector points at least partially upward). In some examples, the normal vectors of the grasping surfaces 141 and 171 have at least an angle of 90 degrees or more between them, and in some cases 135 degrees or more.

The first and second grasping surfaces 141 and 171 are movable towards or away from one another by pivoting of the movable portion 122. Moreover, as described in greater detail below, stops 132 and 142 and strikers 162 and 172 constrain the motion of the movable portion 122 such that the first and second grasping surfaces 141 and 171 can move between two extremes, wherein in a first extreme they are the farthest apart they can be given the constraints and in a second extreme they are the closest together they can be given the constraints. The first and second grasping surfaces 141 and 171 are configured such that, when in the second extreme (closest together), there is a positive angle therebetween greater than zero degrees and less than 90 degrees. Because grasping surfaces 141 and 171 are disposed at a positive angle relative to one another when in the closest extreme, they provide a good griping surface which can allow a user to easily pull the device 100 out of the mounting tray 180, as described above.

The angle referred to herein is measured in a forward opening direction (see angle “α” in FIG. 9 for a visual depiction), meaning that a positive angle implies that the first and second grasping surfaces 141 and 171 diverge from one another when moving in the forward direction and converge towards one another when moving in the rearward direction. In other words, a positive angle implies that the separation distance between the respective front-most edges of the surfaces 141 and 171 exceeds the separation distance between the respective rear-most edges of the surfaces 141 and 171. In contrast, if the first and second grasping surfaces 141 and 171 converge towards one another when moving in the forward direction and diverge from one another when moving the rearward direction (i.e., if the separation distance between the front edges is less than the separation distance between the rear edges), this implies a negative angle therebetween. In some examples, the angle is greater than or equal to 5 degrees. In some examples, the angle is greater than or equal to 10 degrees. In some examples, the angle is greater than or equal to 15 degrees. In some examples, the angle is greater than or equal to 20 degrees. In some examples, the angle is greater than or equal to 30 degrees. In some examples, the angle is less than or equal to 45 degrees. In some examples, the angle is less than or equal to 30 degrees. In some examples, the angle is 15 degrees.

Wireform 123 is disposed between and engaged with the fixed portion 121 and the movable portion 122. The wireform 123 is elastically deformable (within the range of motion of the movable portion 122) and configured to spring-bias the movable portion 122 towards a latched position. Thus, the wireform 123 may help to automatically engage the latch 150 with the latch receiver 182 during insertion, as contact between the latch 150 and the latch receiver 182 during insertion may cause the latch 150 to move either over or under the latch receiver 182 (depending on the example) and then the spring force provided by the wireform 123 may urge the latch 150 back in the opposite direction once the latch engaging portion of the latch 150 is aligned with the latch receiver 182. The wireform 123 may also hold the latch 150 in this engaged state with the latch receiver 182 until a countervailing force (e.g., a user squeezing the grasping surfaces 141 and 171 together) overcomes the spring force.

The movable portion 122 also comprises a first striker 162 (in the middle portion 160) and a second striker 172 (in the movable arm 170). As shown in FIG. 1, the first striker 162 is configured to engage with the first stop 132, and the second striker 172 is configured to engage with the second stop 142. The first and second stops 132 and 142, through their interaction with the first and second strikers 162 and 172, constrain the motion of the movable portion 122 to only rotational motion between a first orientation at one extreme and a second orientation at the other extreme. In particular, engagement (contact) between the first striker 162 and the first stop 132 occurs when the movable portion 122 is at the first orientation and prevents further motion of the movable portion in a first rotational direction (the first rotational direction being the direction of rotation urged by the wireform 123). Conversely, engagement (contact) between the second striker 172 and the second stop 142 occurs when the movable portion 122 is at the second orientation and prevents further motion of the movable portion 122 in a second rotational direction (opposite the first rotational direction). The stops 132 and 142 are provided to prevent the movable portion 122 from moving outside of a desired range of orientations. Over traveling of the latch 150 could result in it colliding with obstacles or failing to engage with the latch receiver 182.

For example, the first orientation, as dictated by the first stop 132, may correspond to a latched position of the latch 150. Because the wireform 123 urges the latch in the first rotational direction, and because the first stop 132 prevents rotation in the first direction beyond the first orientation, the first orientation is also a default orientation of the movable portion 122 (i.e., the position the movable portion 122 tends to enter and stay in when not forced into some other position by an externally applied force). If the movable portion 122 were allowed to rotate in the first rotational direction beyond this first orientation, then the latch 150 may not properly engage with the latch receiver 182 when inserted into the mounting tray 180.

The second orientation, as dictated by the second stop 142, may correspond to the position of the movable portion 122 when the grasping surfaces 141 and 171 have been squeezed together. Stopping the motion of the movable portion 122 at this second orientation may help to ensure that the surfaces 141 and 171 are at a positive angle to one another. In addition, the contact between the second striker 172 and the second stop 142 provides a tactile feedback to the user which lets them know that the handles have been squeezed far enough to disengage the latch, allowing the user to know that they can begin pulling on the handles to remove the device 100. This makes the removal process more intuitive and simpler.

As shown in FIG. 2, the system 101 comprises a rack 190. The rack 190 may be a standard rack as defined by any of the industry rack standards, such as a rack as specified by the EIA-310 standard (promulgated by the Electronics Industries Alliance), the CEA-310-E standard (promulgated by the Consumer Electronics Association), by the IEC 60297 standard (promulgated by International Electrotechnical Commission), or any other industry standard.

As shown in FIG. 2, the system 101 comprises a mounting tray 180 to facilitate mounting of device 100 to rack 190. The mounting tray 180 may comprise a horizontal base and one or more vertical supports coupled to the horizontal base. For example, the vertical supports may include two sidewalls, which may be used to mount the tray 180 to the rails 195, described below. The vertical supports may also include a central vertical divider which divides the mounting tray 180 into two half-width compartments 181, which may also be referred to using the label 181_1 or 181_2 when specifically referencing one in distinction to the other. Each compartment 181 is configured to receive one half-width rack-mountable device, such as the device 100. The device 100 could be installed in either compartment 181. The mounting tray also comprises latch receivers 182. The latch receivers 182 may be attached to the vertical supports of the mounting tray 180 in positions that will allow them to engage with latches 150 of devices 100 inserted into the compartments 181. In particular, a first latch receiver 182_1 is disposed in, or adjacent, the compartment 181_1, while a second latch receiver 182_2 is disposed in, or adjacent, the compartment 181_2. If the device 100 is inserted into the compartment 181_1, then the latch 150 will engage with latch receiver 182_1 to latch the device 100 in the mounting tray 180. If the device 100 is inserted into the compartment 181_2, then the latch 150 will engage with latch receiver 182_2 to latch the device 100 in the mounting tray 180. In some examples, the latch receiver 182_1 is attached to a vertical divider, while the latch receiver 182_2 is attached to a side wall of the tray 180.

In some examples, the mounting tray 180 may be attached directly to the rack 190. In other examples, the mounting tray 180 may be attached to a set of rails 195, and the rails 195 are, in turn, attached to the rack 190. The rails 195 may be sliding (telescoping) rails which can allow the mounting tray 180 to be moved some distance out of the rack without actually detaching the mounting tray 180 from the rack 190.

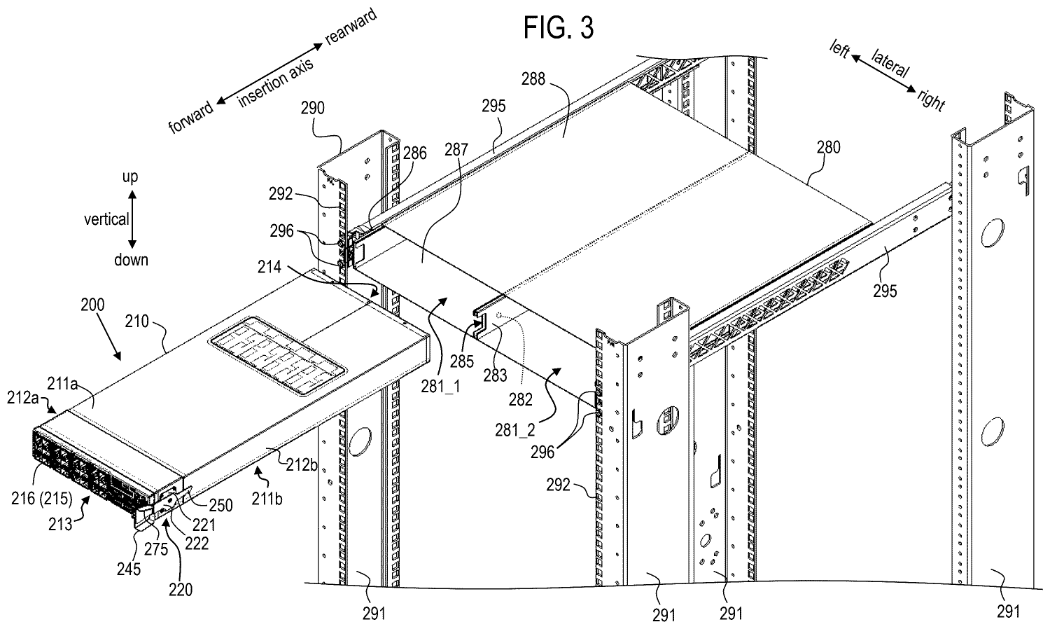

Turning now to FIGS. 3-17, an example half-width rack-mountable information processing device 200 (device 200), an example latch mechanism 220 of the device 200, and an example system 201 comprising the device 200 will be described. The device 200, latch mechanism 220, and system 201 are example implementations of the device 100, latch mechanism 120, and system 101 described above, and some components illustrated in FIGS. 3-17 thus correspond to (i.e., are implementation examples of) components illustrated in FIGS. 1 and 2. Such corresponding components are given similar reference numbers having the same last two digits, such as 110 and 210. In some cases, descriptions above related to aspects of the device 100, latch mechanism 120, or system 101 apply also to the corresponding components of the device 200, latch mechanism 220, and system 201 described below, unless otherwise indicated or logically contradictory, and thus duplicative description of such aspects may be omitted below. Although the device 200, latch mechanism 220, and system 201 are example implementations of the device 100, latch mechanism 120, and system 101, the device 100, latch mechanism 120, and system 101 are not limited to just the device 200, latch mechanism 220, and system 201.

References are made herein to various directional terms, such as lateral, vertical, up, down, left, right, forward, rearward, etc. These terms are used in relation to the device 200 as depicted in the figures and do not have any relationship to any external reference frame, such as the earth. It is noted that the device 200 may be oriented in a variety of directions relative to other objects, and thus in some circumstances the directional terms used herein may have a meaning which differs from how those term terms might be used in relation to some other reference frame. For example, if the device 200 is oriented with its topside facing the ground, then the “up” direction as referenced herein would point toward the ground in that scenario.

As shown in FIG. 3, the system 201 comprises a rack 290, rails 295 attached to the rack 290, a mounting tray 280 attached to the rails 295, and the information processing device 200 which is inserted (or insertable) in the mounting tray 280.

The rack 290 comprises four vertical posts 291. The posts 291 each comprising mounting features 292 in the form of square apertures which are spaced in standardized positions along the height of the posts 291 to define mounting locations for rack-mountable devices.

The rails 295 comprise a pair of sliding/telescoping rails. One rail 295 is positioned on a left lateral side of the rack 290 and is attached to a front left post 291 and a rear left post 291. The other rail 295 is positioned on a right lateral side of the rack 290 and is attached to a front right post 291 and a rear right post 291. The rails 295 are attached to the posts 291 by fasteners 296 which extend through corresponding mounting features 292.

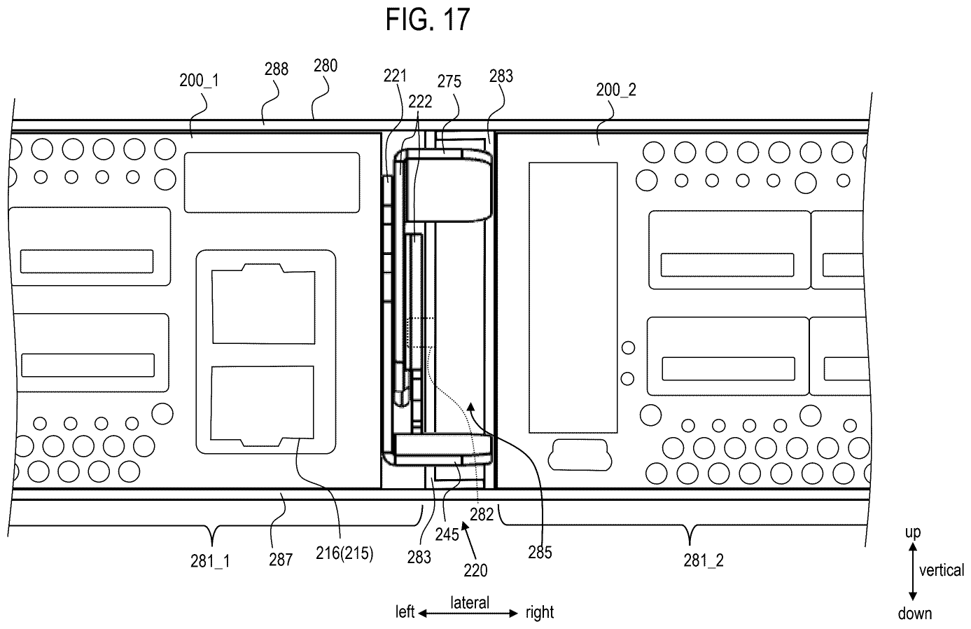

The mounting tray 280 comprises a box-like enclosure having a top horizontal wall 288, a bottom horizontal wall 287, and two vertical side walls 286 (only one is visible in FIG. 3). As shown in FIGS. 3 and 17, the mounting tray 280 also comprises a central vertical divider 283, which divides the mounting tray 280 horizontally into two compartments 281, namely a first compartment 281_1 and a second compartment 281_2. In this example, the divider 283 has two vertical panels which are spaced apart by a small amount, forming a cavity 285 therebetween. The mounting tray 280 also comprises two latch receiver pins 282 (only one is illustrated). FIGS. 3 and 17 show one of the latch receiver pins 282 in dashed lines because it would otherwise be hidden from view in the figures. As shown in FIG. 17, the latch receiver pin protrudes laterally leftward into the compartment 281_1. The other latch receiver pin 282 may be coupled, for example, to a right-side wall 286 of the mounting tray 280 and protrude leftwards into the compartment 281_2.

The information processing device 200 comprises chassis 210. The chassis 210 has two horizontal walls, namely cover 211a and a basepan 211b, and two vertical side walls, namely left sidewall 212a and right sidewall 212b. The chassis 210 also comprises front panel 213 and rear panel 214.

The information processing device 200 also comprises information processing components 215. In the illustrated example, the information processing device 200 is a networking device and one of the information processing components 215 thereof comprises network ports 216, which include connectors (e.g., jacks, sockets) configured to receive complimentary connectors of communication cables. Some of these network ports 216 are disposed in the front panel 213. Some may also be disposed in the rear panel 214 (not illustrated). The device 200 has other information processing components 215 which are not visible in the figure because they are housed within the chassis 210, such as processor(s), switching circuitry, memory, etc.

The device 200 also comprises a latching mechanism 220. The latching mechanism 220 is attached to a sidewall of the chassis 210. In the illustrated example, the latching mechanism is attached to the right sidewall 212b near a front side of the device 200. In other examples it could instead be attached to the left sidewall 212a near the front side of the device 200.

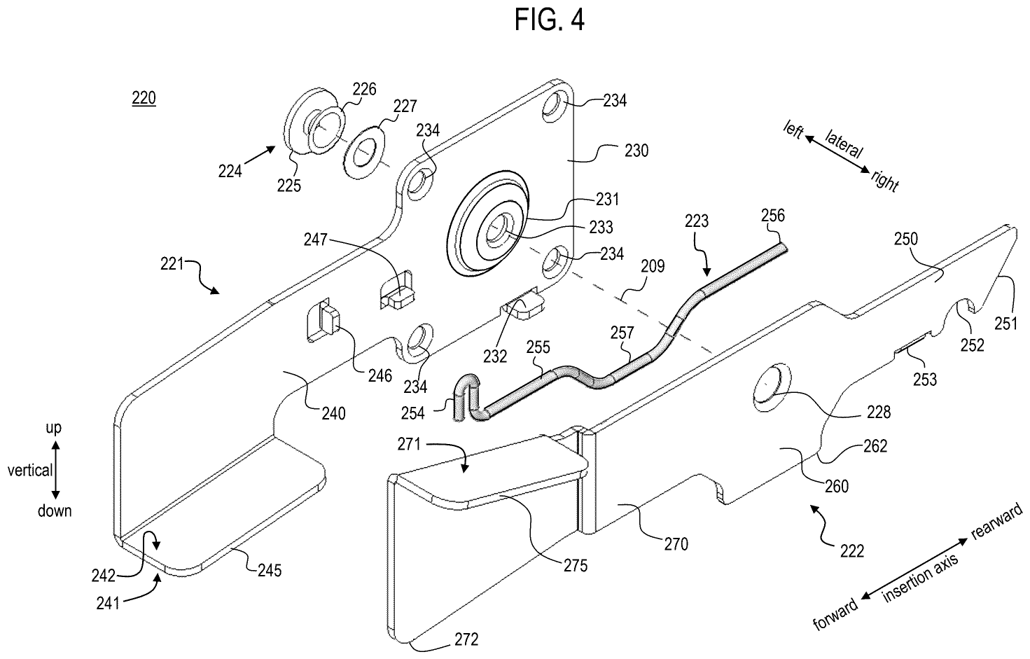

As best seen in FIGS. 4-7, the latching mechanism 220 comprises a fixed portion 221, a movable portion 222 pivotably coupled to the fixed portion, a wireform 223, and a pivot pin 224. These components will be described in turn below.

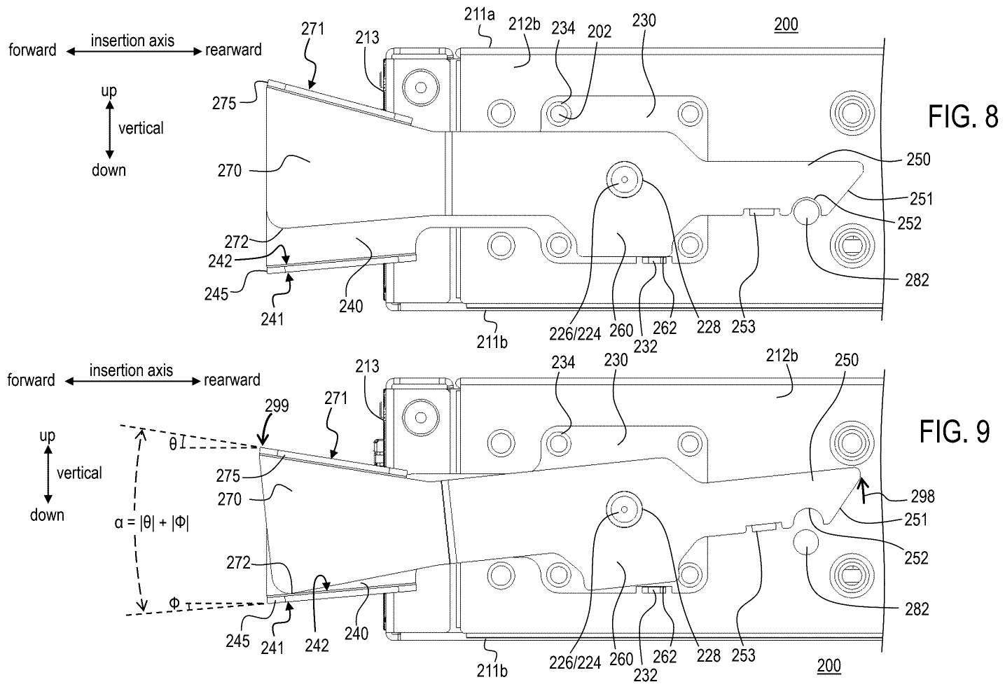

The fixed portion 221 comprises a base 230 which is fixedly attached to the chassis 210. The base 230 may be attached to the chassis 210 by mechanical fasteners 202, which extend through fastener openings 234. In this example, the base 230 has a roughly square-shaped profile and there are four fastener openings 234 positioned at the four corners of the base 230. The mechanical fasteners 202 may be screws, rivets, or other fasteners. In FIG. 8, only one mechanical fastener 202 is labeled, but each opening 234 may have a fastener 202 inserted therethrough. Thus, the fixed portion 221 is stationary relative to the chassis 210. Returning to FIG. 4, the base 230 also comprises a first stop 232 positioned at the bottom edge thereof. The first stop 232 comprises a horizontal flange or tab bent from adjoining vertical portion of the base 230. The base 230 also comprises an attachment portion 231 which receives the pin 224, as described in greater detail below.

Attached to the base 230 is a fixed arm 240. The fixed arm 240 protrudes from the base 230 in a forward direction. In this example, the fixed arm 240 in integrally coupled to the base 230, meaning they are part of the same unitary (e.g., monolithic) body. The fixed arm 240 comprises a vertically oriented portion and a horizontally oriented handle 245 which extends perpendicularly from the vertically oriented portion. The handle 245 has a bottom surface which forms the first grasping surface 241, and a top surface side which forms the first stop 242. The handle 245 protrudes from the mounting tray 280 in the installed state of the device 200 therein. The fixed arm 240 also comprises wireform holder 246. Wireform holder 246 comprises a vertically oriented flange which is bent from and perpendicular to the adjoining vertical portion of the fixed arm 240. Fixed portion 221 also comprises another wireform holder 246, which in the illustrated example is disposed near where the fixed arm 240 and the base 230 join together. The wireform holder 247 comprises a horizontally oriented flange which is bent from and perpendicular to the adjoining vertical portion of the fixed arm 240.

With continued reference to FIG. 4, the movable portion 222 comprises a middle portion 260, which is pivotably coupled to the base 230 of the fixed portion 221 by pivot pin 224. The pivot axis 209 about which the movable portion 222 pivots is parallel to the lateral direction (i.e., the width dimension of the information processing device 200). As noted above, the fixed portion 221 has an attachment portion 231. The attachment portion 231 comprises a dome-like structure which protrudes laterally (rightward towards the movable portion 222) from the surrounding planar face of the base 230. The attachment portion 231 comprises an aperture 233 through which the pin 224 extends. The movable portion 222 also has an aperture 228 through which the pin 224 extends. As shown in FIG. 4, the pivot pin 224 has a flange 225 on one side (the left side in FIG. 4) and another flange 226 on the other side (the right side in FIG. 4). As shown in FIG. 6, when assembled, the flange 225 is positioned on the side of the base 230 which faces the chassis 210 (the left side) inside the cavity defined by the protruding dome of the attachment portion 231. The other flange 226 of the pin 224 is positioned on the side of the middle portion 260 which faces away from the chassis 210 (the right side) inside a chamfered (counter-sunk) portion of the aperture 228. A middle portion of the pin 224 (a portion between the two flanges 226 and 225) extends through the apertures 233 and 228. The flange 225 has a diameter larger than that of the aperture 233 and the flange 226 has a diameter larger than that of the aperture 228, and thus, as shown in FIG. 6, the base 230 and middle portion 260 are clamped together between the flanges 226 and 225, with the middle portion 260 of the movable portion 222 resting against the right-most surface of the protruding attachment portion 231 (the top of the dome). Prior to assembly, the end of the pin 224 which has the flange 226 may have a small enough diameter to fit through the aperture 233 and 228, thus allowing for the pin 224 to be inserted therethrough. After the parts are assembled and the pin 224 is inserted through the aperture 233 and 228, the end of the pin 224 may be deformed (e.g., through pressing, hammering, etc.) to increase its diameter and form the flange 226, thus locking the pin 224 into place.

As shown in FIGS. 4 and 6, a wave washer 227 may be disposed between the flange 225 and the attachment portion 231. The wave washer 227 may be elastically deformable and thus applies spring forces to the flange 225 which pull the middle portion 260 flush against the attachment portion 231 and keep the joint in tension, while still allowing for some compliance (through deformation of the wave washer 227) to avoid binding of the joint. If the pin 224 were tightened enough to hold the middle portion 260 flush against the attachment portion 231 without the washer 227 present, the joint may be too tight and may resist pivoting. On the other hand, if the pin 224 were loosened to avoid such binding, then the middle portion 260 may rattle or vibrate. The elastic deformability of the wave washer 227 can reduce such rattling/vibration by maintaining tension in the joint while also avoiding binding by allowing for some give.

With reference to FIG. 4, the movable portion 222 also comprises a latch 250 protruding in a rearward direction from the middle portion 260. In this example, the latch 250 is integrally coupled to the middle portion 260. The latch 250 comprises a hook 252 in a bottom edge thereof, which forms a latching engagement feature which engages a latch receiver pin 282 of the mounting tray 280 in a manner that latches the device 200 to the mounting tray 280 (i.e., prevents or resists removal of the device 200). For example, FIG. 8 shows the hook 252 engaged with latch receiver pin 282. The latch 250 also comprises a sloped lead-in feature 251. Because the pivot axis about which the movable portion 222 pivots is parallel to the width dimensions, the end of the latch 250 moves vertically up and down along an arc when the movable portion 222 pivots. For example, FIG. 9 shows the latch 250 in a disengaged state, with arrow 298 showing the upward arcing motion of the distal end of the latch 250 which occurs when the latch 250 moves from the engaged state of FIG. 8 to the disengaged state of FIG. 9. Engagement and disengagement of latch 250 will be described in greater detail below.

Returning to FIG. 4, the movable portion 222 also comprises a movable arm 270. The movable arm 270 protrudes in the forward direction from the middle portion 260, i.e., the opposite direction from the latch 250. Thus, the movable arm 270 extends generally parallel to and alongside the fixed arm 240 of the fixed portion 221. In particular, some vertical faces of the movable arm 270 are in sliding contact with vertical faces of the fixed arm 240, which can provide some stability to the movable portion 222 and resist twisting thereof. Like the fixed arm 240, the movable arm 270 comprises a generally vertical portion and a horizontal handle 275 at an end thereof extending perpendicularly rightward from the vertical portion. The handle 275 has top surface which forms the second grasping surface 271. Moreover, because the pivot axis is located between the movable arm 270 and the latch 250, if an upward or downward force is applied to the handle of the movable arm 270, this generates a torque which tends to pivot the movable portion 222 and moves the latch 250 in a direction opposite that of the applied force. In other words, the movable portion 222 acts like a first class (or class one) lever. For example, as shown in FIG. 9, the upward motion of latch 250 indicated by arrow 298 may be caused by a downward motion of the handle 275 indicated by the arrow 299.

As shown in FIGS. 8 and 9, the first and second grasping surfaces 241 and 271 are vertically spaced apart from each other, are aligned/overlapping in a vertical direction, and face in generally opposite directions. Specifically, the handle 275 of the movable arm 270 is positioned vertically above the handle 245 of the fixed arm 240, with second grasping surface 271 facing generally upwards and first grasping surface 241 facing generally downwards. This allows the user to apply a force to the second grasping surface 271 by grasping both the first and second grasping surfaces 241 and 271 between thumb and opposing finger and squeezing the two towards one another.

The first and second grasping surfaces 241 and 271 are movable towards or away from one another by pivoting of the movable portion 222. Moreover, as described in greater detail below, stops 232 and 242 and strikers 262 and 272 constrain the motion of the movable portion 222 such that the first and second grasping surfaces 241 and 271 can move between two extremes, wherein in a first extreme they are the farthest apart they can be given the constraints and a second extreme in they are the closest together they can be given the constraints. FIG. 8 illustrates the latching mechanism 220 in the first extreme when grasping surfaces 241 and 271 are farthest together. FIG. 9 illustrates the latching mechanism 220 in the second extreme when grasping surfaces 241 and 271 are closest together. The first and second grasping surfaces 241 and 271 are configured such that, when in the second extreme (closest together), there is a positive angle “a” therebetween. The angle referred to herein is measured in a forward opening direction as shown in FIG. 9 and described above. Because grasping surfaces 241 and 271 are disposed at positive angle relative to one another when squeezed together, they provide a good griping surface which can allow a user to easily pull the device 200 out of the mounting tray 280, as described above.

As shown in FIG. 9, in this example, not only is there are positive angle α between the grasping surfaces 241 and 271 (i.e., they are tilted relative to one another), the grasping surfaces 241 and 271 are also tilted relative to a horizontal plane. The first grasping surface 241 is tilted downward at an angle ϕ relative to the horizontal, while second grasping surface 271 is tilted upward at an angle θ relative to the horizontal. The angle α may be equal to |θ|+|ϕ| (the bars here indicate that the absolute value of the angles is being added together, meaning the magnitude of the angles without regard to whether they are positive or negative; in other words, |x|=\sqrt{x²}). In this example, 10°≤α≤20°, which provides a good balance between grip, comfort, and ease of use. But in other examples the angle may be larger or smaller.

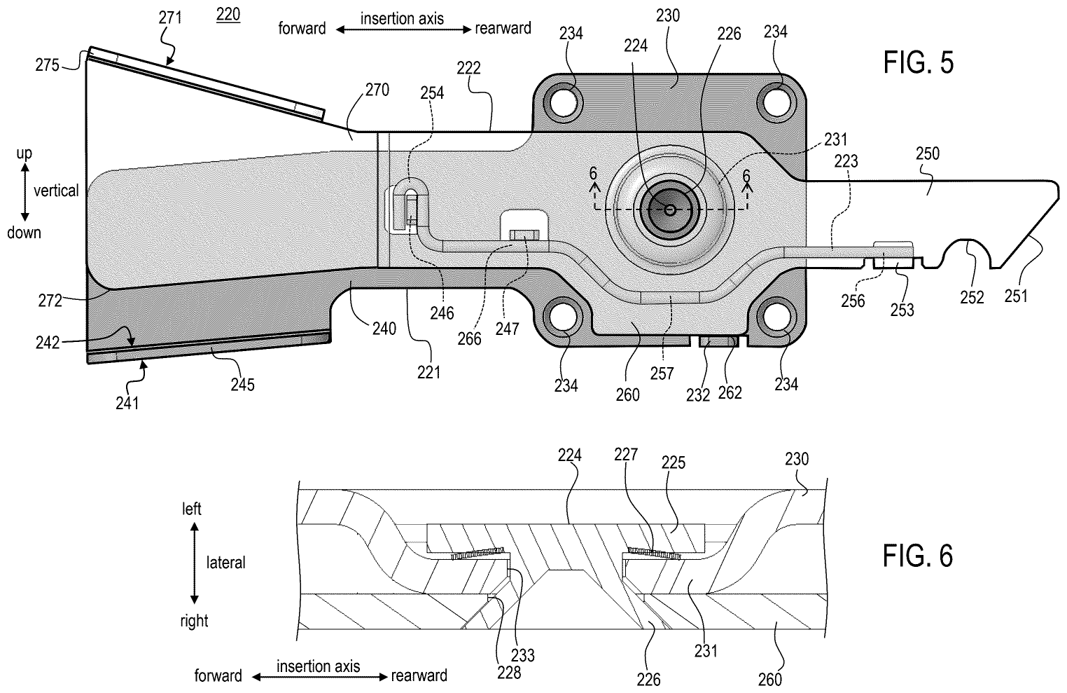

As shown in FIGS. 4-6, wireform 223 is disposed between, and is engaged with, the fixed portion 221 and the movable portion 222. The wireform 223 is elastically deformable (within the range of motion of the movable portion 222) and configured to spring-bias the movable portion 222 towards a latched position. As shown in FIG. 5, the wireform 223 has a hook 254 at one end which is engaged with the wireform holder 246 of the fixed portion 221. The opposite end portion 256 of the wireform 223 is engaged with the wireform holder 253 of the movable portion 222. An intermediate portion 266 of the wireform 223 is engaged with the wireform holder 247 of the fixed portion 221. The intermediate portion 266 of the wireform 223 acts like a fulcrum such that, if the end portion 256 is moved upward (e.g., because the latch 250 is moved upward), the wireform 223 attempts to pivot counter-clockwise about the intermediate portion 266. However, because the hook end 254 is engaged with the wireform holder 246, the wireform 223 cannot rotate about the fulcrum. Thus, the wireform 223 must elastically deform instead. This elastic deformation generates restoring spring forces which resist the upward movement of the end portion 256 and urge it to move back downward toward the latched position shown in FIG. 8. Moreover, the wireform 223 may be pre-tensioned such that it applies a downward spring force even when the latch 250 is in the latched position. Thus, the wireform 223 may help to automatically engage the latch 250 with the latch receiver 282 during insertion, as described below, and may also hold the latch 250 in this engaged state with the latch receiver 282 until a countervailing force overcomes the spring force. Returning to FIGS. 5 and 6, it is noted that the protruding attachment portion 231 holds the middle portion 260 of the movable portion 222 spaced apart from the base 230 of the fixed portion 221 by a predetermined distance (except at the attachment portion 231 itself). This spacing allows room for the wireform 223 to be disposed between the fixed portion 221 and the movable portion 222. The wireform 223 may include a valley 257 between wireform holders 247 and 253. Moving rearward from the wireform holder 247, the valley 257 which dips down to bypass the attachment portion 231 and then subsequently turns back upwards to allow for engagement with wireform holder 253, as shown in FIG. 5

As noted above, the movable portion 222 also comprises a first striker 262 (in the middle portion 260) and a second striker 272 (in the movable arm 270). The first striker 262 comprises a bottom edge of the middle portion 260 near a bottom/rear corner thereof. The second striker 272 comprises a bottom edge of the of the movable arm 270 near a bottom/front corner thereof. As shown in FIGS. 5 and 8, the first striker 262 is configured to engage with the first stop 232, and as shown in FIG. 9, the second striker 272 is configured to engage with the second stop 242. The first and second stops 232 and 242, through their interaction with the first and second strikers 262 and 272, constrain the motion of the movable portion 222 to only rotational motion between a first orientation at one extreme and a second orientation at the other extreme. FIG. 8 illustrates the movable portion 222 in the first orientation in which engagement (contact) between the first striker 262 and the first stop 232 occurs. This engagement prevents further motion of the movable portion 222 in a first rotational direction (clockwise relative to the view in FIG. 8), where the first rotational direction is the direction of rotation urged by the wireform 223. FIG. 9 illustrates the movable portion 222 in the second orientation in which engagement (contact) between the second striker 272 the second stop 242 occurs. This engagement prevents further motion of the movable portion 222 in a second rotational direction (opposite the first rotational direction) (counterclockwise in FIG. 9). Note that the first orientation of the movable portion 222 shown in FIG. 8 also correspond to a latched position of the latch 250 and to the first extreme of the grasping surfaces 241 and 271 in which they are farthest apart. Similarly, the second orientation of the movable portion 222 shown in FIG. 9 also correspond to an unlatched position of the latch 250 and to the second extreme of the grasping surfaces 241 and 271 in which they are closest together. Because the wireform 223 urges the latch in the first rotational direction, and because the first stop 232 prevents rotation in the first direction beyond the first orientation, the first orientation is also a default orientation of the movable portion 222 (i.e., the position the movable portion 222 tends to enter and stay in when not forced into some other position by an externally applied force).

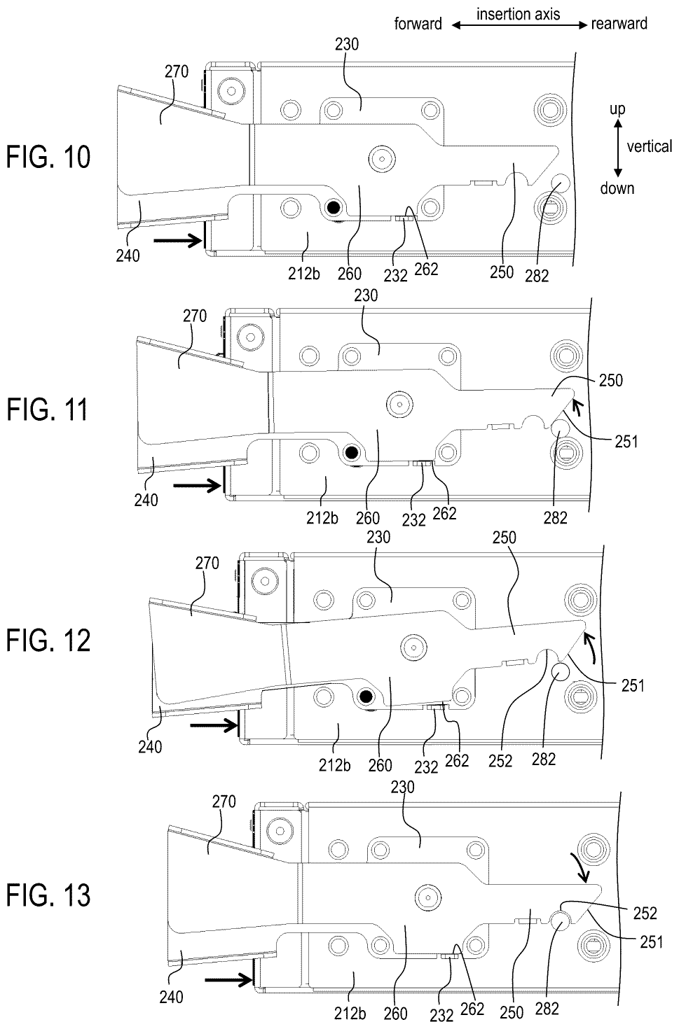

Turning to FIGS. 10-13, a process of installing the device 200 in the mounting tray 280 will be described. The process begins by inserting the device 200 rearward along the insertion axis into one of the compartments 281 of the tray 280, with a rear panel 214 of the device 200 being inserted first as suggested by FIG. 3. The device 200 is then advanced rearward in the compartment 281, resulting in the state illustrated in FIG. 10.

As the device 200 continues to be advanced rearward, eventually the sloped lead-in 251 of the latch 250 contacts the latch receiver pin 282 of the compartment 281, as shown in FIG. 11. The sloped surface of the lead-in 251 translates this contact into upward motion of the end of the latch 250, as indicated by the arrows in FIG. 11. The wireform 223 resists this upward motion of the latch 250, but the rearward momentum of the device 200 together with pushing forces applied by the user to the device 200 overcome the resistance of the wireform 223 and the latch 250 thus rises.

Continued rearward sliding of the device 200 causes the receiver pin 282 to traverse the length of the lead-in 251, further raising up the end of the latch 250, as indicated by the arrows in FIG. 12. (Again, this rise is resisted by wireform 223, but is overcome by forces supplied by the user).

Eventually the lead-in 251 moves rearward beyond receiver pin 282 and the recessed portion of the hook 252 becomes aligned with the receiver pin 282. Because the lead-in 251 is no holding the latch 250 upward against the spring force of the wireform 223, the now un-resisted spring force causes the latch 250 to snap back downward, with the receiver pin 282 being received into the recessed portion of the hook 252, as shown in FIG. 13. The wireform 223 thereafter holds the latch 250 in engagement with the latch receiver pin 282. Engagement between a rear edge of the hook 252 and rear edge of the latch receiver pin 282 prevents the device 200 from moving in the forward direction. The state illustrated in FIG. 13 corresponds to an installed state of the device 200.

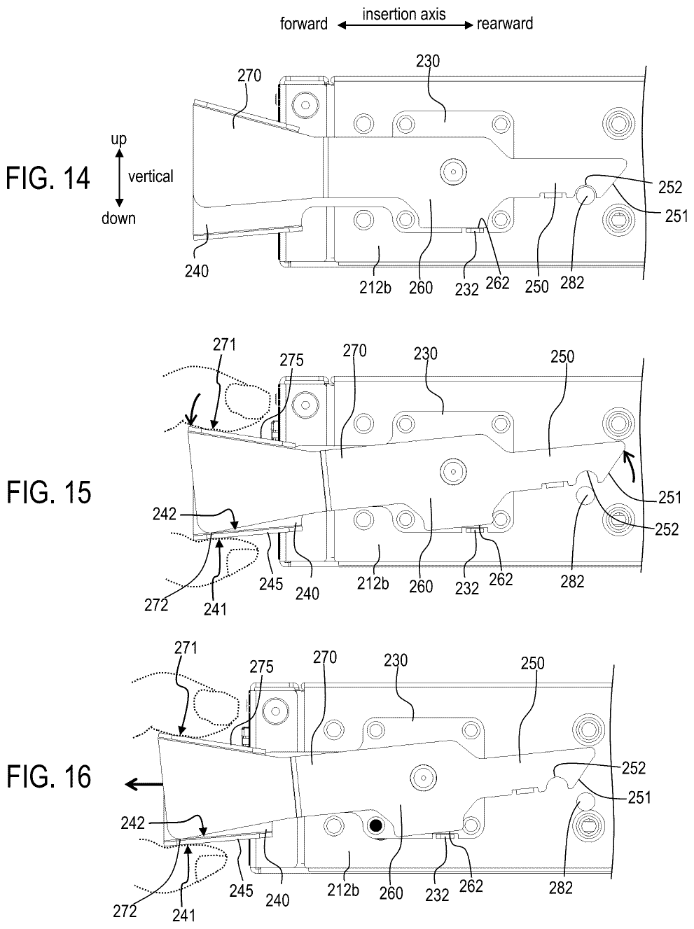

Turning to FIGS. 14-16, a process of installing the device 200 in the mounting tray 280 will be described. The process begins with the device 200 in the installed state, as shown in FIG. 14. While in this state, a user may grasp the grasping surfaces 241 and 271 of the handles 245 and 275 with opposing fingers and squeeze the grasping surfaces 241 and 271 towards one another. This results in the grasping surface 271 moving in an arc downward, as indicated by the downward arrow in FIG. 15, which in turn causes the latch 250 to move upward as indicated by the upward arrow in FIG. 15. Quickly, the striker 272 will come into contact with the stop 242, as shown in FIG. 15, which arrests the downward motion for the grasping surface 271. This corresponds to the above-described second extreme of the grasping surfaces 241 and 271. At this point, the latch 250 is disengaged from the latch receiver pin 282 and the device 200 is ready to be withdrawn from the tray 280. The contacting of the striker 272 with the stop 242 and the stopping of motion can provide tactile feedback to the user to signal that the disengagement has been completed.

Subsequently, while continuing to squeeze the grasping surfaces 241 and 271, the user pulls on the handles 245 and 275 in a forward direction along the insertion axis, as indicated by the forward arrow in FIG. 16. This causes the device 200 to begin moving forward out of the compartment 181. Eventually, the latch 250 will move forward past the latch receiver 282, as shown FIG. 16. Further forward movement of the device 200 will result in the device 200 eventually exiting the compartment 181. Thus, the latching mechanism 220 can act not only as the latching mechanism but also as a removal handle. This dual use can save space, as a separate removal handle is not needed.

Notably, the process described above of removing the device 200 can, in some cases, be performed using just one hand. For example, the same hand which squeezes the handles 245 and 275 together in FIG. 15 can pull the handles 245 and 275 forward in FIG. 16 as part of the same action or in a continuous succession of actions. This can make the removal easier and provide more flexibility for the user to use their other hand for other tasks at the same time, such as supporting an underside of the device 200, pulling out an adjoining device at the same time, holding a tool, etc. In addition, the squeezing (gripping) force the user needs to supply to hold onto the handles is much less than it would be if the handles had, for example, parallel gripping surfaces.

Furthermore, in addition to saving space by allowing a removal handle to be omitted, the latching mechanism 220 itself can be very space efficient in the highly space constrained context of half-width devices. For example, as shown in FIG. 17, the portion of the latching mechanism 220 which sits between the device 200_1 and the internal divider 283 is relatively narrow in the lateral dimension, occupying only about as much space as three sheet metal pieces (about 4 mm). Thus, very little lateral space is taken away from the device 200 to accommodate the latching mechanism 220. Moreover, as shown in FIG. 17, while the handles 245 and 275 do occupy more lateral space, they protrude from the mounting tray 280 and thus do not take up space which would otherwise be occupied by the device 200. Furthermore, in some examples, the handles 245 and 275 do not interfere with insertion/removal of the adjacent device 200_2 because the handles 245 and 275, while protruding rightward beyond the bounds of the first compartment 281_1, to not cross into the bounds of the second compartment 281_2. This is because there is a central divider 283 between the first and second compartments 281_2 and 281_2, and the handles 245 and 275 protrude rightward only as far as the space occupied by the central divider 283. In this manner, the handles 245 and 275 can be laterally wide enough to provide enough area for an effective grip to be obtained but without encroaching on the space needed by the device 200 or interfering with an adjacent device.

In noted above, in the example illustrated in FIGS. 3-17, one of the latch receiver pins 282 is provided in the central divider 283 protruding leftward into the first compartment 281_1 and the other is provided in a right side wall of the mounting tray 280 protruding leftward into the second compartment 281_2. However, it should be understood that the same latching mechanism 220 could work with other arrangements of the mounting tray 280. For example, in some implementations, the latch receiver pin positioning is reversed, with a first latch receiver pin be attached to a left side wall of the mounting tray 280 and protruding rightward into the first compartment 281_1 and a second latch receiver pin attached to a right side of the central divider 283 and protruding rightward into the second compartment 281_2. In such examples, the devices 200 may be modified to position the latching mechanism 220 on the left sides of their chassis 210 and to laterally mirror the latching mechanism 220 relative to the depiction herein.

In still other examples, both latch receiver pins are positioned on opposite side walls of the mounting tray 280 with none of the latch receiver pins positioned on the central divider 283. In such examples, devices 200 which are inserted into the compartment 281_1 may have their latching mechanism 220 positioned on the left side thereof with an orientation laterally mirrored relative to that shown herein, whereas device 200 which are inserted into the compartment 281_2 may have their latching mechanism 220 positioned on the right side thereof with the orientation shown herein.

Furthermore, in the example shown in FIGS. 3-17, the latch 250 moves over the latch receiver pin 282 and upward movement of the latch 250 (corresponding to downward movement of the handle 275) is used to disengage the latch from the pin 282. However, in other examples, the latching mechanism 220 could be vertically mirrored relative to the orientations shown herein. In such examples, the latch 250 moves under the latch receiver pin 282 and downward movement of the latch 250 (corresponding to upward movement of the handle 275) is used to disengage the latch from the pin 282.

In the description above, various types of electronic circuitry are described. As used herein, “electronic” is intended to be understood broadly to include all types of circuitry utilizing electricity, including digital and analog circuitry, direct current (DC) and alternating current (AC) circuitry, and circuitry for converting electricity into another form of energy and circuitry for using electricity to perform other functions. In other words, as used herein there is no distinction between “electronic” circuitry and “electrical” circuitry.

It is to be understood that both the general description and the detailed description provide examples that are explanatory in nature and are intended to provide an understanding of the present disclosure without limiting the scope of the present disclosure. Various mechanical, compositional, structural, electronic, and operational changes may be made without departing from the scope of this description and the claims. In some instances, well-known circuits, structures, and techniques have not been shown or described in detail in order not to obscure the examples. Like numbers in two or more figures represent the same or similar elements.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Elements and their associated aspects that are described in detail with reference to one example may, whenever practical, be included in other examples in which they are not specifically shown or described. For example, if an element is described in detail with reference to one example and is not described with reference to a second example, the element may nevertheless be claimed as included in the second example.

Unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within +1% of the stated value, property, or relationship unless indicated otherwise.

Further modifications and alternative examples will be apparent to those of ordinary skill in the art in view of the disclosure herein. For example, the devices and methods may include additional components or steps that were omitted from the diagrams and description for clarity of operation. Accordingly, this description is to be construed as illustrative only and is for the purpose of teaching those skilled in the art the general manner of carrying out the present teachings. It is to be understood that the various examples shown and described herein are to be taken as exemplary. Elements and materials, and arrangements of those elements and materials, may be substituted for those illustrated and described herein, parts and processes may be reversed, and certain features of the present teachings may be utilized independently, all as would be apparent to one skilled in the art after having the benefit of the description herein. Changes may be made in the elements described herein without departing from the scope of the present teachings and following claims.

It is to be understood that the particular examples set forth herein are non-limiting, and modifications to structure, dimensions, materials, and methodologies may be made without departing from the scope of the present teachings.

Other examples in accordance with the present disclosure will be apparent to those skilled in the art from consideration of the specification and practice of the invention disclosed herein. It is intended that the specification and examples be considered as exemplary only, with the following claims being entitled to their fullest breadth, including equivalents, under the applicable law.

What is claimed is:

1. An information processing device comprising:
a chassis configured to be insertable into a half-width compartment of a mounting tray attached or attachable to a rack;
information processing components supported by the chassis; and
a latching mechanism comprising:
a fixed portion comprising a first grasping surface; and
a movable portion pivotably coupled to the fixed portion and comprising a latch and a second grasping surface,
wherein the second grasping surface is movable between a first extreme and a second extreme,
wherein in the first extreme, the first and second grasping surfaces are farthest apart and the latch is in a latching position,
wherein in the second extreme, the first and second grasping surfaces are closet together and the latch is in an unlatched position;
wherein the first and second grasping surfaces have, while in the second extreme, a positive non-zero angle therebetween.

2. The information processing device of claim 1,
wherein the latch comprises a latching engagement element configured to, in the latching position of the latch and in an installed state of the chassis in the compartment, engage with a latch receiver of the mounting tray and secure the information processing device to mounting tray.

3. The information processing device of claim 2,
wherein the latch engagement element comprises a hook and the latch receiver comprises a pin, the hook configured to receive the pin.

4. The information processing device of claim 1,
wherein the fixed portion comprises a base attached to the chassis and a fixed arm protruding in a first direction from the base, the fixed arm comprising a handle comprising the first grasping surface; and
wherein the movable portion comprises a middle portion pivotably coupled to the base of the fixed portion and a movable arm protruding from the middle portion in the first direction, wherein the latch protrudes from the middle portion in a second direction opposite the first direction, wherein the movable arm comprises a second handle comprising the second grasping surface.

5. The information processing device of claim 4,
wherein the latching mechanism comprises a wireform disposed between, and engaged with each of, the fixed portion and the movable portion, the wireform configured to spring bias the latch towards the latching position.

6. The information processing device of claim 4,
wherein the latching mechanism comprises a pivot pin engaged with the base of the fixed portion and the middle portion of the movable portion.

7. The information processing device of claim 6,
wherein the base of the fixed portion comprises an attachment portion which protrudes laterally from the base and comprises a first aperture,
wherein the middle portion of the movable portion rests against the attachment portion and comprises a second aperture;
wherein the pivot pin extends through the first and second aperture and comprises a first flange on a first side of the attachment portion within a cavity defined thereby and a second flange on a second side of the middle portion of the movable portion.

8. The information processing device of claim 4,
wherein the first and second grasping surfaces are vertically aligned and face in opposite directions.

9. The information processing device of claim 4,
wherein the fixed portion comprises a first stop and a second stop;
wherein the movable portion comprises a first striker and a second striker;
wherein the first striker is configured to engage the first stop at a first orientation of the movable portion corresponding to the first extreme of the second grasping surface and prevent movement beyond the first orientation; and
wherein the second striker is configured to engage the second stop at a second orientation of the movable portion corresponding to the second extreme of the second grasping surface and prevent movement beyond the second orientation.

10. The information processing device of claim 9,
wherein the first stop comprises a horizontal flange protruding perpendicularly form the base of the fixed portion and the first striker comprises an edge of the middle portion of the movable portion.

11. The information processing device of claim 9,
wherein the second stop comprises a surface of the first handle of the fixed arm and the second striker comprises an edge of the movable arm.

12. An information processing system comprising:
a rack configured to hold a plurality of rack-mountable devices; and
a mounting tray mounted to the rack, the mounting tray comprising two half-width compartments configured to receive two half-width rack-mountable devices, respectively; and
at least one instance of the information processing device of claim 1 inserted into one of the compartments of the mounting tray,
wherein the latch of the information processing device is in the latching position and comprises a latching engagement element engaged with a latch receiver of the mounting tray and securing the information processing device to mounting tray.

13. The information processing system of claim 12,
wherein the latch engagement element comprises a hook and the latch receiver comprises a pin, the hook configured to receive the pin.

14. The information processing system of claim 12,
wherein the fixed portion comprises a base attached to the chassis and a fixed arm protruding in a first direction from the base, the fixed arm comprising a handle comprising the first grasping surface; and
wherein the movable portion comprises a middle portion pivotably coupled to the base of the fixed portion and a movable arm protruding from the middle portion in the first direction, wherein the latch protrudes from the middle portion in a second direction opposite the first direction, wherein the movable arm comprises a second handle comprising the second grasping surface.

15. The information processing system of claim 14,
wherein the latching mechanism comprises a wireform disposed between, and engaged with each of, the fixed portion and the movable portion, the wireform configured to spring bias the latch towards the latching position.

16. The information processing system of claim 14,
wherein the latching mechanism comprises a pivot pin engaged with the base of the fixed portion and the middle portion of the movable portion.

17. The information processing system of claim 14,
wherein the first and second grasping surfaces are vertically aligned and face in opposite directions.

18. The information processing system of claim 14,
wherein the fixed portion comprises a first stop and a second stop;
wherein the movable portion comprises a first striker and a second striker;
wherein the first striker is configured to engage the first stop at a first orientation of the movable portion corresponding to the first extreme of the second grasping surface and prevent movement beyond the first orientation; and
wherein the second striker is configured to engage the second stop at a second orientation of the movable portion corresponding to the second extreme of the second grasping surface and prevent movement beyond the second orientation.

19. A method comprising:
in an installed state of the information processing device of claim 1 in a compartment of a mounting tray attached to a rack, grasping the first and second grasping surfaces and disengaging the latch from a latch receiver of the mounting try by squeezing the first and second grasping surfaces together and moving the second grasping surface to the second extreme; and
while squeezing the first and second grasping surfaces with the second grasping surface at the second extreme, pulling the information processing device out of the compartment by pulling the first and second grasping surfaces along a direction parallel to an insertion axis of the information processing device into the compartment.

20. The method of claim 19,
wherein the disengaging of the latch and the pulling of the information processing device out of the compartment are performed using a single hand to squeeze and pull on the first and second latching surfaces.
